(19) United States
(12) Patent Application Publication
(10) Pub. No.: US 2012/0112853 A1
(43) Pub. Date: May 10, 2012

(54) TUNABLE FILTER, TUNABLE DUPLEXER AND MOBILE COMMUNICATION TERMINAL USING THE SAME

(76) Inventors: Osamu HIKINO, Yokohama (JP); Takashi Shiba, Yokosuka (JP); Naoko Kamogawa, Yokohama (JP); Akio Yamamoto, Hiratsuka (JP); Masazumi Tone, Ebina (JP)

(21) Appl. No.: 13/221,487

(22) Filed: Aug. 30, 2011

(30) Foreign Application Priority Data
Nov. 5, 2010 (JP) JP 2010-248047

(51) Int. Cl. H01P 1/10; H03H 7/48; H01P 1/20; H03H 7/01

(52) U.S. Cl. 333/132; 333/105; 333/174

(57) ABSTRACT

A tunable filter and a tunable duplexer are provided, both of which comprise an input terminal, an output terminal, four fixed capacitors, three variable capacitors and three fixed coils; wherein the variable capacitors are grounded at one end and, at the other end, connected to the fixed coils to form three sets of series-connected LC circuit; wherein the connecting points of the three sets of series-connected LC circuit, the input terminal and the output terminal are connected with the fixed capacitors, respectively.

### BACKGROUND OF THE INVENTION

The present invention relates to a tunable (frequency-variable) filter and a tunable duplexer, both for mobile communication terminals, and a mobile communication terminal using them.

New mobile communications technologies currently being considered for use on mobile phones include WCDMA, which is already in service, and LTE. WCDMA and LTE allow simultaneous transmission and reception and therefore use different frequency bands for transmission and reception. These communication systems use a duplexer that separates the transmission band and the reception band.

The WCDMA and the LTE systems each have a plurality of frequency bands and, to produce desired high-frequency characteristics, use a duplexer for each frequency band in a mobile communication terminal front end. Further the LTE system requires the same number of reception circuits as the antennas since it employs a MIMO (Multiple Input Multiple Output) technology to realize high-speed communication. So, as the communication grows in speed in future, the scale of the reception circuit is expected to become large, calling for a new technology to render the duplexers tunable. Patent Literature 1 (JP-A-2011-120120) describes a tunable filter technology to switch the duplexer into a tunable state and a canceler technology to cancel leakage components of a transmitted signal found in a received signal output from the tunable filter and thermal noise leakage components in the reception band. So, although the amount by which out-of-band signals are suppressed by the tunable filter is about 20 dB smaller than that suppressed by a conventional untunable duplexer or a frequency-fixed duplexer, the tunable filter, when used in combination with the canceler technology, can be put into practical use.

With the conventional tunable filters, a high-frequency filter has been formed, as described in Patent Literature 2 (JP-A-2010-45478), by connecting three meander line inductors formed on a dielectric substrate, five transmission lines approximately λ/4 long and three varactors with their one end grounded to make the capacitance of the varactors variable.

### SUMMARY OF THE INVENTION

The technology described in the Patent Literature 2 has a drawback that the filter becomes large in size because a number of meander line inductors and λ/4-long transmission lines are formed on a dielectric substrate. This problem becomes conspicuous especially when a tunable filter is constructed in low frequency ranges because the meander line inductors and the λ/4-long transmission lines become long.

In the WCDMA and LTE systems, specifications on Band1-Band17 have already been defined and the number of bands tends to further increase in future. For mobile communication terminals capable of handling these multiple bands, an effective solution involves making the duplexer tunable to reduce the size of their front end portion and also minimizing the size of the tunable filter.

It is an object of this invention to provide a mobile communication terminal that performs transmission and reception operations simultaneously by using different frequency bands for transmission and reception and which is small in size and highly reliable and can handle a plurality of frequency bands.

To make improvements on the aforementioned problem, a tunable filter is used which comprises: an input terminal; an output terminal; a first series-connected LC circuit composed of a first variable capacitor and a first fixed coil; a second series-connected LC circuit composed of a second variable capacitor and a second fixed coil; a third series-connected LC circuit composed of a third variable capacitor and a third fixed coil; a first fixed capacitor with one of its ends connected to the input terminal and the other end connected to a connecting point of the first variable capacitor and the first fixed coil; a second fixed capacitor with one of its ends connected to the output terminal and the other end connected to a connecting point of the second variable capacitor and the second fixed coil; a third fixed capacitor with one of its ends connected to the connecting point of the first variable capacitor and the first fixed coil and the other end connected to a connecting point of the third variable capacitor and the third fixed coil; and a fourth fixed capacitor with one of its ends connected to the connecting point of the second variable capacitor and the second fixed coil and the other end connected to the connecting point of the third variable capacitor and the third fixed coil; wherein the frequencies of a passband and a stopband of the tunable filter are made variable by changing capacitance values of the variable capacitors.

With this invention, a mobile communication terminal can be provided which is small and highly reliable and can handle a plurality of frequency bands.

Other objects, features and advantages of the invention will become apparent from the following description of the embodiments of the invention taken in conjunction with the accompanying drawings.

### BRIEF DESCRIPTION OF THE DRAWINGS

FIG. 1 is a circuitry showing an example configuration of a tunable filter tuned to relatively high frequencies in a first embodiment of this invention.

FIG. 2 shows a frequency characteristic of a receiving filter tuned to a highest frequency band in Band1 in the tunable filter of the first embodiment.

FIG. 3 shows frequency characteristic of a receiving filter tuned to a lowest frequency band in Band3 in the tunable filter of the first embodiment.

FIG. 4 is a circuitry showing an example configuration of a tunable filter for relatively low frequencies in a second embodiment of this invention.

FIG. 5 shows a frequency characteristic of a receiving filter tuned to a highest frequency band in Band3 in the tunable filter of the second embodiment.

FIG. 6 shows a frequency characteristic of a receiving filter tuned to a lowest frequency band in Band17 in the tunable filter of the second embodiment.

FIG. 7 shows a circuitry of a tunable filter module as a third embodiment of this invention.

FIG. 8 shows a circuitry of a tunable duplexer tuned to relatively high frequencies as a fourth embodiment of this invention.

FIG. 9 shows a frequency characteristic of the duplexer of the fourth embodiment tuned to a highest frequency band in Band1.

FIG. 10 shows a frequency characteristic of the duplexer of the fourth embodiment tuned to a lowest frequency band in Band3.

FIG. 11 shows a circuitry of a tunable duplexer tuned to relatively low frequencies as a fifth embodiment of this invention.

FIG. 12 shows a frequency characteristic of the duplexer of the fifth embodiment tuned to a highest frequency band in Band8.

FIG. 13 shows a frequency characteristic of the duplexer of the fifth embodiment tuned to a lowest frequency band in Band17.

FIG. 14 shows a circuitry of a tunable duplexer module as a sixth embodiment of this invention.

FIG. 15A is a circuit block diagram showing as a seventh embodiment a multiband-enabled mobile communication terminal that applies the tunable filter module and the tunable duplexer module; and FIG. 15B shows an example of frequency bands available to the tunable duplexer.

### DETAILED DESCRIPTION OF THE EMBODIMENTS

Embodiments of this invention will be described as follows.

### Embodiment 1

FIG. 1 is a circuitry showing an example configuration of a tunable filter tuned to relatively high frequencies in the first embodiment. This tunable filter is obtained as a pass-through characteristic in a direction from an input terminal 1H to an output terminal 2H, or in a reverse direction.

The tunable filter has a first fixed capacitor 3H connected between an input terminal 1H and a connecting point of a first pair of a variable capacitor 10H and a fixed coil 7H; a second fixed capacitor 4H connected between the connecting point of the first pair of the variable capacitor 10H and the fixed coil 7H and a connecting point of a second pair of a variable capacitor 11H and a fixed coil 8H and; a third fixed capacitor 5H connected between the connecting point of the second pair of the variable capacitor 11H and the fixed coil 8H and a connecting point of a third pair of a variable capacitor 12H and a fixed coil 9H; and a fourth fixed capacitor 6H connected between the connecting point of the third pair of the variable capacitor 12H and the fixed coil 9H and an output terminal 2H, with one end of the variable capacitors 10H, 11H, 12H, whose opposite end is connected to the fixed coils 7H, 8H, 9H, grounded and with one end of the fixed coils 7H, 8H, 9H, whose opposite end is connected to the variable capacitors 10H, 11H, 12H, connected together.

This tunable filter is characterized in that the frequency of a passband that is formed by a resonant circuit composed of the fixed capacitors 3H, 6H, the fixed coils 7H, 9H and the variable capacitors 10H, 12H and the frequency of a stopband (notch) that is formed by a resonant circuit composed of the fixed coil 8H and the variable capacitor 11H are made variable by changing the capacitance values of the variable capacitors 10H, 11H, 12H.

Here, the fixed coils 7H, 8H, 9H have constants of about 4.3 nH, 4.1 nH and 4.3 nH, respectively, and use solenoid coils with Q values of about 90 at the operation frequencies. The fixed capacitors 3H, 4H, 5H, 6H have constants of about 0.41 pF, 0.01 pF, 0.01 pF and 0.41 pF, respectively. Since the fixed capacitors 4H and 5H have very small values of capacitance, they can be provided, respectively, by a stray capacitance formed between lands mounting the fixed coil 7H and the fixed coil 8H and by a stray capacitance formed between lands mounting the fixed coil 8H and the fixed coil 9H. In practical use, this allows for a size reduction of the device by not actually mounting these fixed capacitors. The fixed capacitors 3H, 6H are constructed of a chip capacitor. As for constants of the variable capacitors, the variable capacitors 10H, 12H are in a range of between about 0.8 pF and 1.35 pF and the variable capacitor 11H in a range of between about 1.53 pF and 2.07 pF, allowing the filter characteristic to be variable from the highest frequency channel in the Band1 reception band to the lowest frequency channel in the Band3 reception band. That is, the constant of this tunable filter is distributed symmetric between the input terminal 1H side and the output terminal 2H side with respect to the second pair of the variable capacitor 11H and the fixed coil 8H located at the center. The variable capacitors 10H, 11H, 12H are constructed of MEMS variable capacitors.

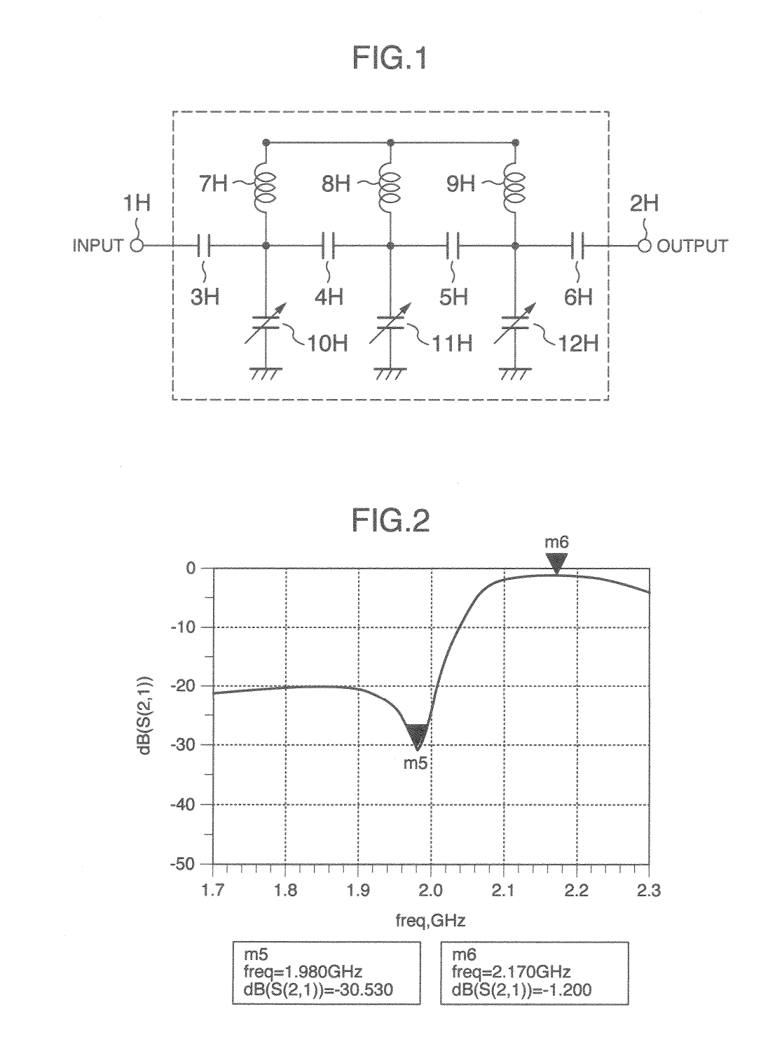

FIG. 2 shows a frequency characteristic of a receiving filter of the tunable filter of the first embodiment tuned to the highest frequency band of Band1, with the variable capacitors 10H and 12H at 0.8 pF and the variable capacitor 11H at 1.53 pF. As shown in FIG. 2, the Band1 receiving filter has a passband at the highest frequency band (2.17 GHz) in Band1 and a stopband at the highest frequency band (1.98 GHz) in the transmission band of Band1.

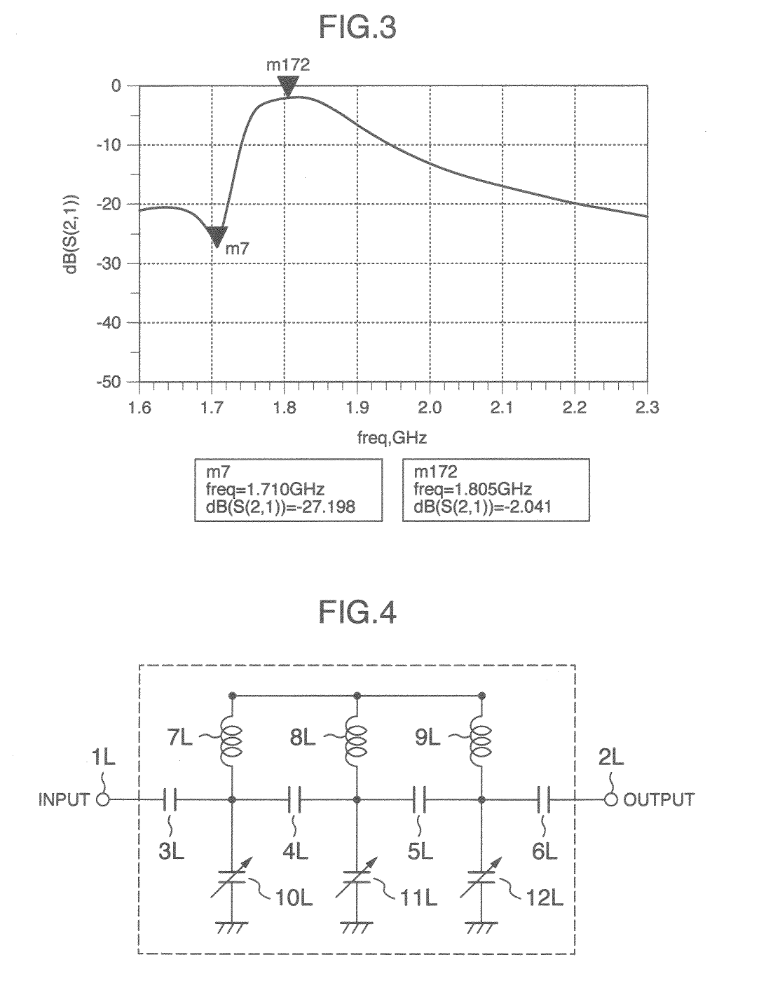

FIG. 3 shows a frequency characteristic of a receiving filter tuned to the lowest frequency band in Band3, with the variable capacitors 10H and 12H at 1.35 pF and the variable capacitor 11H at 2.07 pF. As shown in FIG. 3, the Band3 receiving filter has a passband at the lowest frequency band (1.805 GHz) in Band3 and a stopband at the lowest frequency band (1.71 GHz) in the transmission band of Band3.

From FIG. 2 and FIG. 3, making the variable capacitors 10H, 12H variable in a range from about 0.8 pF to 1.35 pF and the variable capacitor 11H variable in a range from about 1.53 pF to 2.07 pF allows the tunable filter to deal also with those bands included in the frequency range of Band1 and Band3, such as Band2, Band4 and Band9.

### Embodiment 2

FIG. 4 is a circuitry showing a configuration of a tunable filter tuned to relatively low frequencies in a second embodiment. This tunable filter is obtained as a pass-through characteristics in a direction from an input terminal 1L to an output terminal 2L, or in a reverse direction.

A first fixed capacitor 3L is connected between the input terminal 1L and a connecting point of a first pair of a variable capacitor 10L and a fixed coil 7L; a second fixed capacitor 4L is connected between the connecting point of the first pair of the variable capacitor 10L and the fixed coil 7L and a connecting point of a second pair of a variable capacitor 11L and a fixed coil 8L; a third fixed capacitor 5L is connected between the connecting point of the second pair of the variable capacitor 11L and the fixed coil 8L and a connecting point of a third pair of a variable capacitor 12L and a fixed coil 9L; and a fourth fixed capacitor 6L is connected between the connecting point of the third pair of the variable capacitor 12L and the fixed coil 9L, with one end of the variable capacitors 10L, 11L, 12L, the opposite end of which is connected to the fixed coils 7L, 8L, 9L, grounded and with one end of the fixed coils 7L, 8L, 9L, opposite end of which is connected to the variable capacitors 10L, 11L, 12L, connected together.

Similar to the operating principle explained in the first embodiment, the tunable filter is characterized in that its applied band frequency can be varied by changing the capacitance values of the variable capacitors 10L, 11L, 12L.

Here, the fixed coils 7L, 8L, 9L have constants of about 11.5 nH, 7.9 nH and 11.5 nH, respectively, and use solenoid coils with Q values of about 90 for the operation frequencies. The fixed capacitors 3L, 4L, 5L, 6L have constants of about 0.83 pF, 0.15 pF, 0.15 pF and 0.83 pF, respectively. Since the fixed capacitors 4L and 5L have very small values of capacitance, they can be provided, respectively, by a stray capacitance formed between lands mounting the fixed coil 7L and the fixed coil 8L and by a stray capacitance formed between lands mounting the fixed coil 8L and the fixed coil 9L. In practical use, this allows for a size reduction of the device by not actually mounting these fixed capacitors. The fixed capacitors 3L, 6L are constructed of a chip capacitor. As for constants of the variable capacitors, the variable capacitors 10L, 12L are in a range of between about 1.20 pF and 3.02 pF and the variable capacitor 11L in a range of between about 3.12 pF and 5.77 pF, allowing the filter characteristic to be variable from the highest frequency channel in the Band8 reception band to the lowest frequency channel in the Band17 reception band. That is, the constant of this tunable filter is symmetrically distributed between the input terminal 1L side and the output terminal 2L side with respect to the second pair of the variable capacitor 11L and the fixed coil 8L located at the center. The variable capacitors 10L, 11L, 12L are constructed of MEMS variable capacitors.

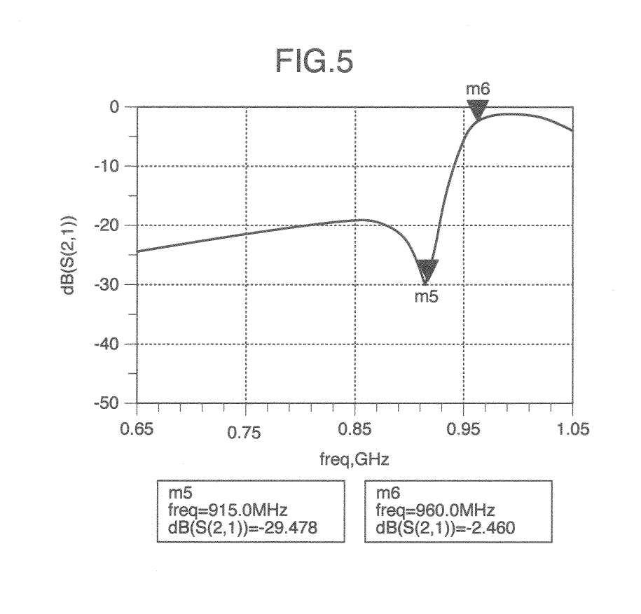

FIG. 5 shows a frequency characteristic of a receiving filter of the tunable filter of the second embodiment tuned to the highest frequency band of Band8, with the variable capacitors 10L and 12L at 1.2 pF and the variable capacitor 11L at 3.12 pF. As shown in FIG. 5, the Band8 receiving filter has a passband at the highest frequency band (0.96 GHz) in Band8 and a stopband at the highest frequency band (0.915 GHz) in the transmission band of Band8.

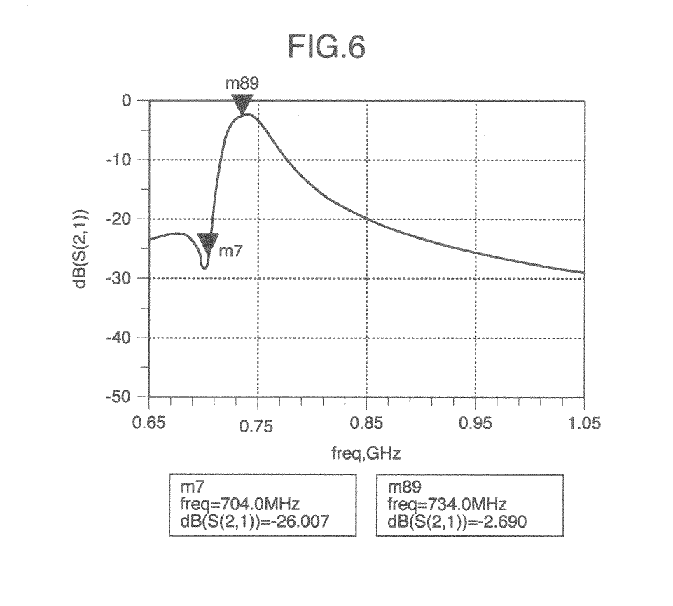

FIG. 6 shows a frequency characteristic of a receiving filter tuned to the lowest frequency band in Band 17, with the variable capacitors 10L and 12L at 3.02 pF and the variable capacitor 11L at 5.77 pF. As shown in FIG. 6, the Band17 receiving filter has a passband at the lowest frequency band (0.734 GHz) in Band17 and a stopband at the lowest frequency band (0.704 GHz) in the transmission band of Band17.

From FIG. 5 and FIG. 6, making the variable capacitors 10L, 12L variable in a range from about 1.2 pF to 3.02 pF and the variable capacitor 11L in a range from about 3.12 pF to 5.77 pF allows the tunable filter to also handle those bands included in the frequency range of Band8 and Band17, such as Band5 and Band6.

### Embodiment 3

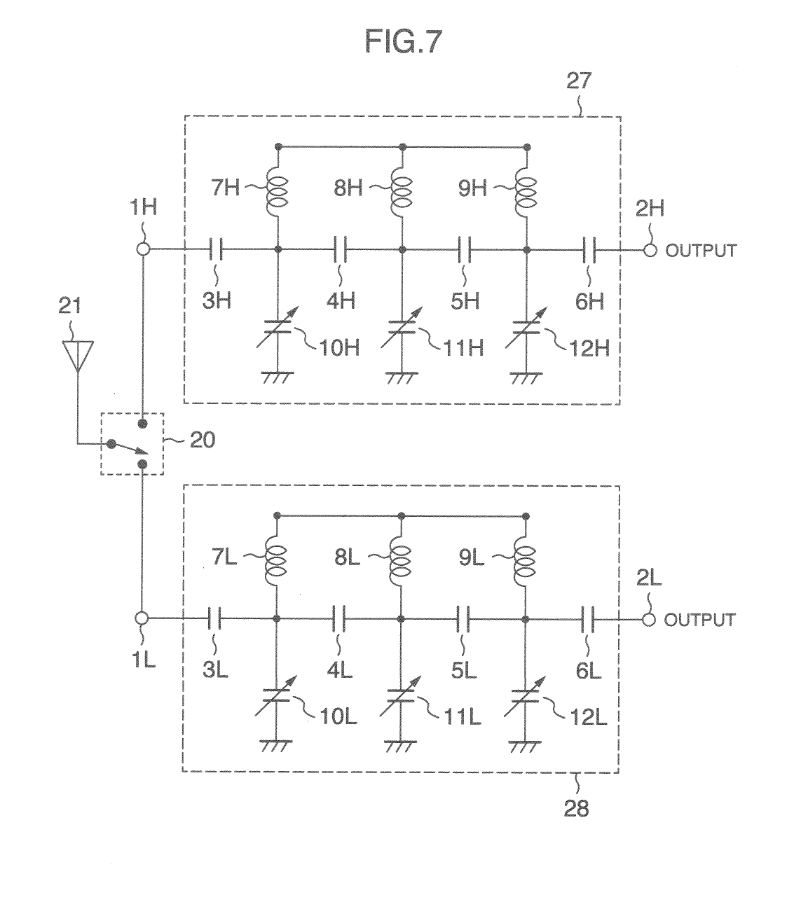

FIG. 7 shows a circuitry of a tunable filter module of the third embodiment. In this embodiment, a high-band tunable filter 27 uses the tunable filter of the first embodiment and a low-band tunable filter 28 the tunable filter of the second embodiment. An input terminal 1H of the high-band tunable filter 27 and an input terminal 1L of the low-band tunable filter 28 are connected to an antenna 21 through a SPDT (Single Pole Dual Throw) switch 20. That is, the SPDT switch 20 selects between the high-band tunable filter 27 and the low-band tunable filter 28 for connection to the antenna 21. The SPDT switch is formed of CMOS, SOS (Silicon on Sapphire) or GaAs switch. The tunable filter module of this configuration can be used as a diversity receiver circuit that covers almost all bands used in communication systems, such as WCDMA and LTE.

### Embodiment 4

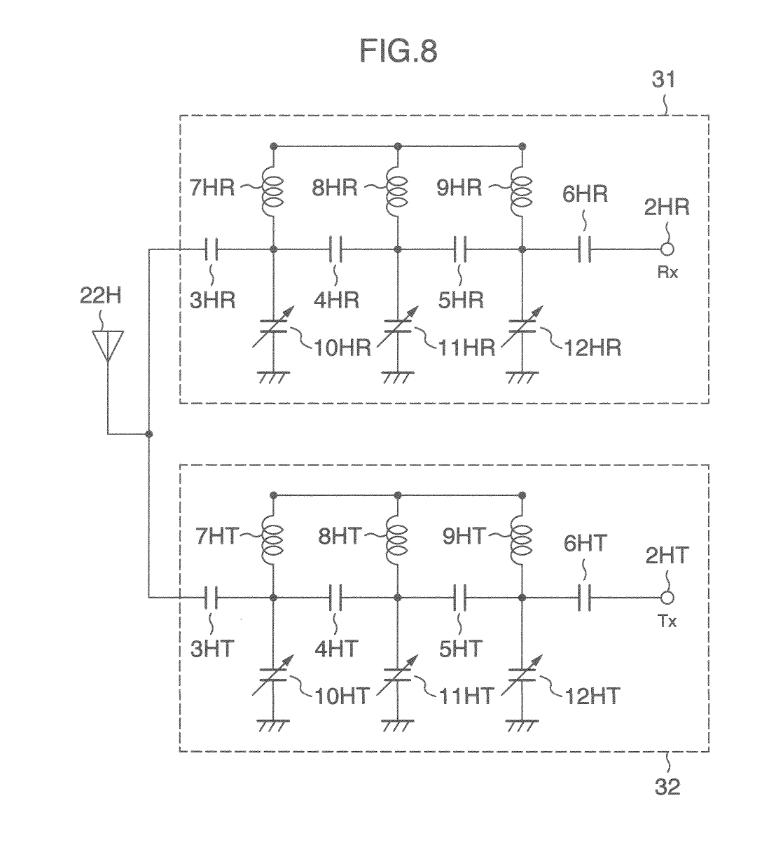

FIG. 8 shows a circuitry of a tunable duplexer tuned to relatively high frequencies in the fourth embodiment. As shown in FIG. 8, input terminals of a receiving tunable filter 31 and a transmitting tunable filter 32 are connected to an antenna 22H to form a tunable duplexer that splits the received signals and transmission signals. The configuration of the tunable filter is the same as that of the tunable filter of the first embodiment. The operating principle that makes the passband and the stopband tunable is the same as that explained in the first embodiment. The configuration of the receiving tunable filter 31 will be described as follows.

A first fixed capacitor 3HR is connected between the antenna 22H and a connecting point of a first pair of a variable capacitor 10HR and a fixed coil 7HR; a second fixed capacitor 4HR is connected between the connecting point of the first pair of the variable capacitor 10HR and the fixed coil 7HR and a connecting point of a second pair of a variable capacitor 11HR and a fixed coil 8HR; a third fixed capacitor 5HR is connected between the connecting point of the second pair of the variable capacitor 11HR and the fixed coil 8HR and a connecting point of a third pair of a variable capacitor 12HR and a fixed coil 9HR; and a fourth fixed capacitor 6HR is connected between the connecting point of the third pair of the variable capacitor 12HR and the fixed coil 9HR and a receiving terminal 2HR, with one end of the variable capacitors 10HR, 11HR, 12HR, whose opposite end is connected to the fixed coils 7HR, 8HR, 9HR, grounded and with one end of the fixed coils 7HR, 8HR, 9HR, whose opposite end is connected to the variable capacitors 10HR, 11HR, 12HR, connected together. The receiving tunable filter 31 is characterized in that its applied band frequency can be varied by changing the capacitance values of the variable capacitors 10HR, 11HR, 12HR.

Here, the fixed coils 7HR, 8HR, 9HR have constants of about 4.3 nH, 4.1 nH and 4.3 nH, respectively, and use solenoid coils with Q values of about 90 at the operation frequencies. The fixed capacitors 3HR, 4HR, 5HR, 6HR have constants of about 0.41 pF, 0.01 pF, 0.01 pF and 0.41 pF, respectively. Since the fixed capacitors 4HR and 5HR have very small values of capacitance, they can be provided, respectively, by a stray capacitance formed between lands mounting the fixed coil 7HR and the fixed coil 8HR and by a stray capacitance between lands mounting the fixed coil 8HR and the fixed coil 9HR. In practical use, this allows for a size reduction of the device by not actually mounting these fixed capacitors. The fixed capacitors 3HR, 6HR are composed of a chip capacitor. As for constants of the variable capacitors, the variable capacitors 10HR, 12HR are in a range of between about 0.8 pF and 1.35 pF and the variable capacitor 11HR in a range of between about 1.53 pF and 2.07 pF, allowing the filter characteristic to be varied from the highest frequency channel in the Band1 reception band to the lowest frequency channel in the Band3 reception band. That is, this tunable filter has its constant distributed symmetrically between the antenna 22H side and the receiving terminal 2HR side with respect to the second pair of the variable capacitor 11HR and the fixed coil 8HR located at the center. The variable capacitors 10HR, 11HR, 12HR are constructed of MEMS variable capacitors.

Next, the configuration of the transmitting tunable filter 32 will be explained.

A first fixed capacitor 3HT is connected between the antenna 22H and a connecting point of a first pair of a variable capacitor 10HT and a fixed coil 7HT; a second fixed capacitor 4HT is connected between the connecting point of the first pair of the variable capacitor 10HT and the fixed coil 7HT and a connecting point of a second pair of a variable capacitor 11HT and a fixed coil 8HT; a third fixed capacitor 5HT is connected between the connecting point of the second pair of the variable capacitor 11HT and the fixed coil 8HT and a connecting point of a third pair of a variable capacitor 12HT and a fixed coil 9HT; and a fourth fixed capacitor 6HT is connected between the connecting point of the third pair of the variable capacitor 12HT and the fixed coil 9HT and a transmitting terminal 2HT, with one end of the variable capacitors 10Ht, 11HT, 12HT, whose opposite end is connected to the fixed coils 7HT, 8HT, 9HT, grounded and with one end of the fixed coils 7HT, 8HT, 9HT, whose opposite end is connected to the variable capacitors 10HT, 11HT, 12HT, connected together.

The transmitting tunable filter 32 is characterized in that its applied band frequency can be varied by changing the capacitance values of the variable capacitors 10HT, 11HT, 12HT.

Here, the fixed coils 7HT, 8HT, 9HT have constants of about 4.4 nH, 4.5 nH and 4.4 nH, respectively, and use solenoid coils with Q values of about 90 at the operation frequencies. The fixed capacitors 3HT, 4HT, 5HT, 6HT have constants of about 0.67 pF, 0.01 pF, 0.01 pF and 0.67 pF, respectively. Since the fixed capacitors 4HT and 5HT have very small capacitances, they can be provided, respectively, by a stray capacitance formed between lands mounting the fixed coil 7HT and the fixed coil 8HT and by a stray capacitance formed between lands mounting the fixed coil 8HT and the fixed coil 9HT. In practical use, this allows the device to be reduced in size by not actually mounting these fixed capacitors. The fixed capacitors 3HT, 6HT are constructed of a chip capacitor. As for constants of the variable capacitors, the variable capacitors 10HT, 12HT are in a range of between about 0.95 pF and 1.50 pF and the variable capacitor 11HT in a range of between about 1.16 pF and 1.7 pF, allowing the filter characteristic to be varied from the highest frequency channel in the Band1 transmission band to the lowest frequency channel in the Band3 transmission band. That is, this tunable filter has its constant distributed symmetrically between the antenna 22H side and the transmitting terminal 2HT side with respect to the second pair of the variable capacitor 11HT and the fixed coil 8HT located at the center. The variable capacitors 10HT, 11HT, 12HT are constructed of MEMS variable capacitors.

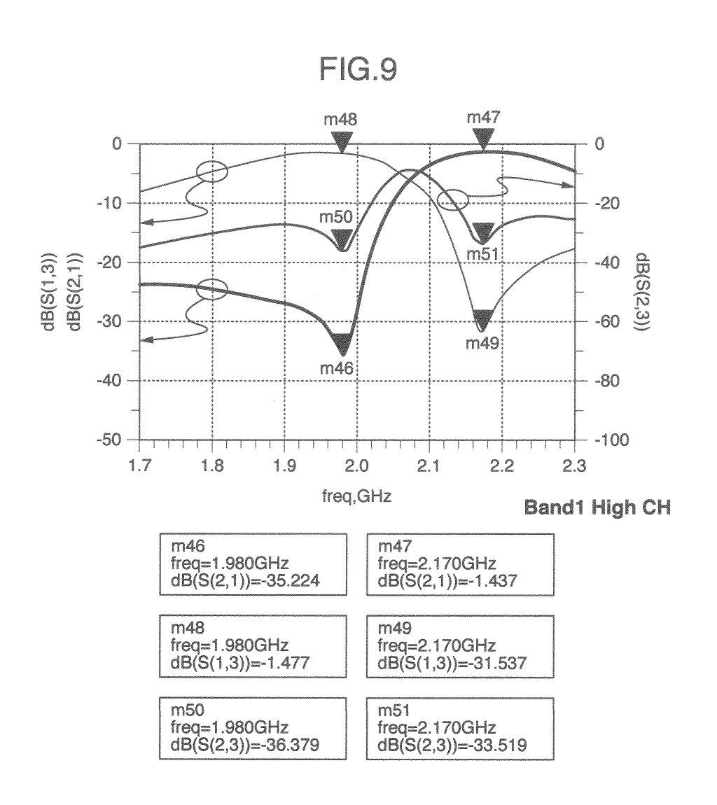

FIG. 9 shows a frequency characteristic of a tunable duplexer of the fourth embodiment tuned to the highest frequency band in Band1, with the variable capacitors 10HR, 12HR at 0.8 pF, the variable capacitor 11HR at 1.53 pF, the variable capacitors 10HT, 12HT at 0.95 pF and the variable capacitor 11HT at 1.16 pF. In FIG. 9, a thick line represents a pass-through characteristic in a direction from the antenna 22H to the receiving terminal 2HR and a thin line represents a pass-through characteristic in a direction from the transmitting terminal 2HT to the antenna 22H, and a medium thin line an isolation characteristic in a direction from the transmitting terminal 2HT to the receiving terminal 2HR.

As shown in FIG. 9, the resonant frequency of the second pair of the variable capacitor 11HR and the fixed coil 8HR in the receiving tunable filter 31 matches the passband of the transmitting tunable filter 32, thus forming a notch. Further, the resonant frequency of the second pair of the variable capacitor 11HT and the fixed coil 8HT in the transmitting tunable filter 32 matches the passband of the receiving tunable filter 31, thus forming a notch. This results in a satisfactory isolation characteristic in a direction from the transmitting terminal 2HT to the receiving terminal 2HR.

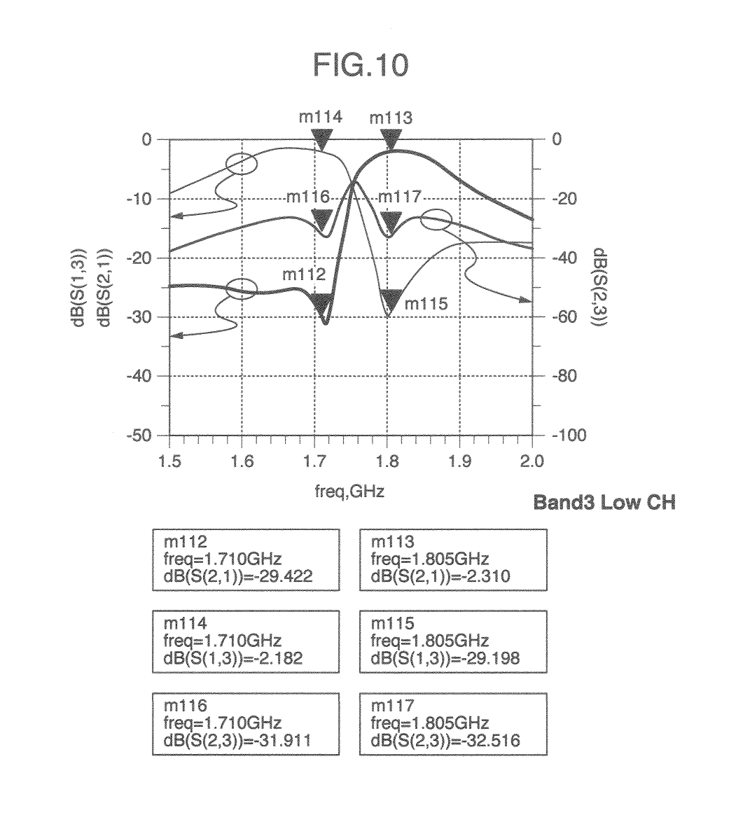

FIG. 10 shows a frequency characteristic of the tunable duplexer of the fourth embodiment tuned to the lowest frequency band in Band3, with the variable capacitors 10HR, 12HR at 1.35 pF, the variable capacitor 11HR at 2.05 pF, the variable capacitors 10HT, 12HT at 1.50 pF and the variable capacitor 11HT at 1.7 pF. In FIG. 10, a thick line represents a pass-through characteristic in a direction from the antenna 22H to the receiving terminal 2HR, a thin line represents a pass-through characteristic in a direction from the transmitting terminal 2HT to the antenna 22H and a medium thin line an isolation characteristic in a direction from the transmitting terminal 2HT to the receiving terminal 2HR. As shown in FIG. 10, the resonant frequency of the second pair of the variable capacitor 11HR and the fixed coil 8HR in the receiving tunable filter 31 matches the passband of the transmitting tunable filter 32, thus forming a notch. Further, the resonant frequency of the second pair of the variable capacitor 11HT and the fixed coil 8HT in the transmitting tunable filter 32 matches the passband of the receiving tunable filter 31, thus forming a notch. This results in a satisfactory isolation characteristic in a direction from the transmitting terminal 2HT to the receiving terminal 2HR.

### Embodiment 5

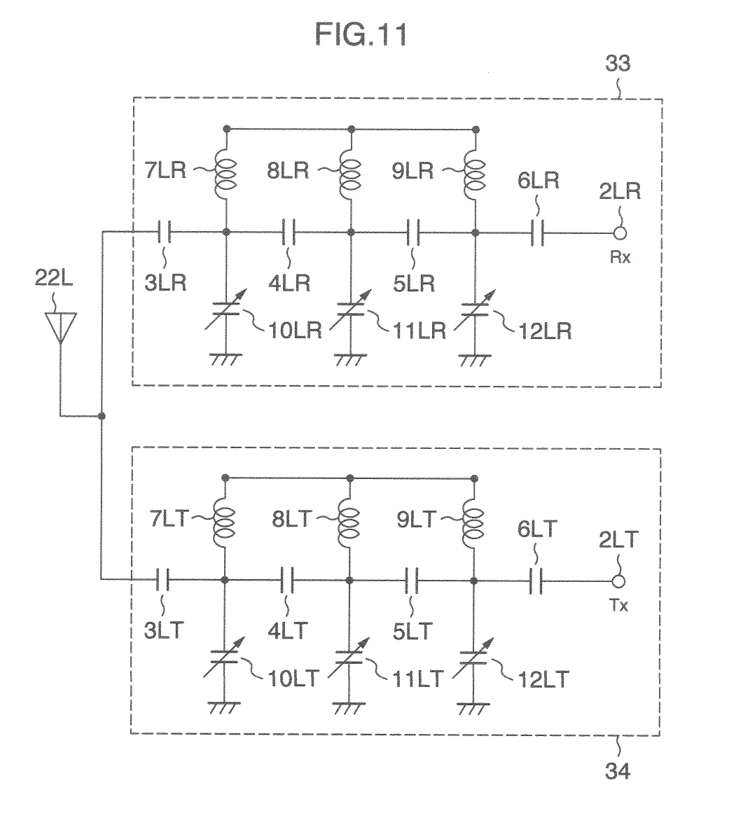

FIG. 11 shows a circuitry of a tunable duplexer tuned to relatively low frequencies in the fifth embodiment. As shown in FIG. 11, input terminals of a receiving tunable filter 33 and a transmitting tunable filter 34 are connected to an antenna 22L to form a tunable duplexer that splits the received signals and sending signals. The configuration of the tunable filter is the same as that of the tunable filter of the first embodiment. The operating principle that makes the passband and the stopband tunable is the same as that explained in the first embodiment. The configuration of the receiving tunable filter 33 will be explained in the following.

A first fixed capacitor 3LR is connected between the antenna 22L and a connecting point of a first pair of a variable capacitor 10LR and a fixed coil 7LR; a second fixed capacitor 4LR is connected between the connecting point of the first pair of the variable capacitor 10LR and the fixed coil 7LR and a connecting point of a second pair of a variable capacitor 11LR and a fixed coil 8LR; a third fixed capacitor SLR is connected between the connecting point of the second pair of the variable capacitor 11LR and the fixed coil 8LR and a connecting point of a third pair of a variable capacitor 12LR and a fixed coil 9LR; and a fourth fixed capacitor 6LR is connected between the connecting point of the third pair of the variable capacitor 12LR and the fixed coil 9LR and a receiving terminal 2LR, with one end of the variable capacitors 10LR, 11LR, 12LR, whose opposite end is connected to the fixed coils 7LR, 8LR, 9LR, grounded and with one end of the fixed coils 7LR, 8LR, 9LR, whose opposite end is connected to the variable capacitors 10LR, 11LR, 12LR, connected together. The receiving tunable filter 33 is characterized in that its applied band frequency can be varied by changing the capacitance values of the variable capacitors 10LR, 11LR, 12LR.

Here, the fixed coils 7LR, 8LR, 9LR have constants of about 11.5 nH, 7.92 nH and 11.5 nH, respectively, and use solenoid coils with Q values of about 90 at the operation frequencies. The fixed capacitors 3LR, 4LR, 6LR, 6LR have constants of about 0.83 pF, 0.15 pF, 0.15 pF and 0.83 pF, respectively. Since the fixed capacitors 4LR and 5LR have very small capacitances, they can be provided, respectively, by a stray capacitance formed between lands mounting the fixed coil 7LR and the fixed coil 8LR and by a stray capacitance formed between lands mounting the fixed coil 8LR and the fixed coil 9LR. In practical use, this allows the device to be reduced in size by not actually mounting these fixed capacitors. The fixed capacitors 3LR, 6LR are constructed of a chip capacitor. As for constants of the variable capacitors, the variable capacitors 10LR, 12LR are in a range of between about 1.2 pF and 3.02 pF and the variable capacitor 11LR in a range of between about 3.15 pF and 5.8 pF, allowing the filter characteristic to be varied from the highest frequency channel in the Band8 reception band to the lowest frequency channel in the Band17 reception band. That is, this tunable filter has its constant distributed symmetrically between the antenna 22L side and the receiving terminal 2LR side with respect to the second pair of the variable capacitor 11LR and the fixed coil 8LR located at the center. The variable capacitors 10LR, 11LR, 12LR are constructed of MEMS variable capacitors.

Next, the configuration of the transmitting tunable filter 34 will be explained.

A first fixed capacitor 3LT is connected between the antenna 22L and a connecting point of a first pair of a variable capacitor 10LT and a fixed coil 7LT; a second fixed capacitor 4LT is connected between the connecting point of the first pair of the variable capacitor 10LT and the fixed coil 7LT and a connecting point of a second pair of a variable capacitor 11LT and a fixed coil 8LT; a third fixed capacitor 5LT is connected between the connecting point of the second pair of the variable capacitor 11LT and the fixed coil 8LT and a connecting point of a third pair of a variable capacitor 12LT and fixed coil 9LT; and a fourth fixed capacitor 6LT is connected between the connecting point of the third pair of the variable capacitor 12LT and the fixed coil 9LT and a transmitting terminal 2LT, with one end of the variable capacitors 10LT, 11LT, 12LT, whose opposite end is connected to the fixed coils 7LT, 8LT, 9LT, grounded and with one end of the fixed coils 7LT, 8LT, 9LT, whose opposite end is connected to the variable capacitors 10LT, 11LT, 12LT, connected together.

The transmitting tunable filter 34 is characterized in that its applied band frequency can be varied by changing the capacitance values of the variable capacitors 10LT, 11LT, 12LT.

Here, fixed coils 7LT, 8LT, 9LT have constants of about 14.5 nH, 7.5 nH and 14.5 nH, respectively, and use solenoid coils with Q values of about 90 at the operation frequencies. The fixed capacitors 3LT, 4LT, 5LT, 6LT have constants of about 1.32 pF, 0.3 pF, 0.3 pF and 1.32 pF, respectively. Since the fixed capacitors 4LT and 5LT have very small capacitances, they can be provided, respectively, by a stray capacitance formed between lands mounting the fixed coil 7LT and the fixed coil 8LT and by a stray capacitance formed between lands mounting the fixed coil 8LT and the fixed coil 9LT. In practical use, this allows the device to be reduced in size by not actually mounting these fixed capacitors. The fixed capacitors 3LT, 6LT are constructed of a chip capacitor. As for constants of the variable capacitors, the variable capacitors 10LT, 12LT are in a range of between about 0.88 pF and 2.30 pF and the variable capacitor 11LT in a range of between about 2.11 pF and 4.55 pF, allowing the filter characteristic to be varied from the highest frequency channel in the Band8 transmission band to the lowest frequency channel in the Band17 transmission band. That is, this tunable filter has its constant distributed symmetrically between the antenna 22L side and the transmitting terminal 2LT side with respect to the second pair of the variable capacitor 11LT and the fixed coil 8LT located at the center. The variable capacitors 10LT, 11LT, 12LT are constructed of MEMS variable capacitors.

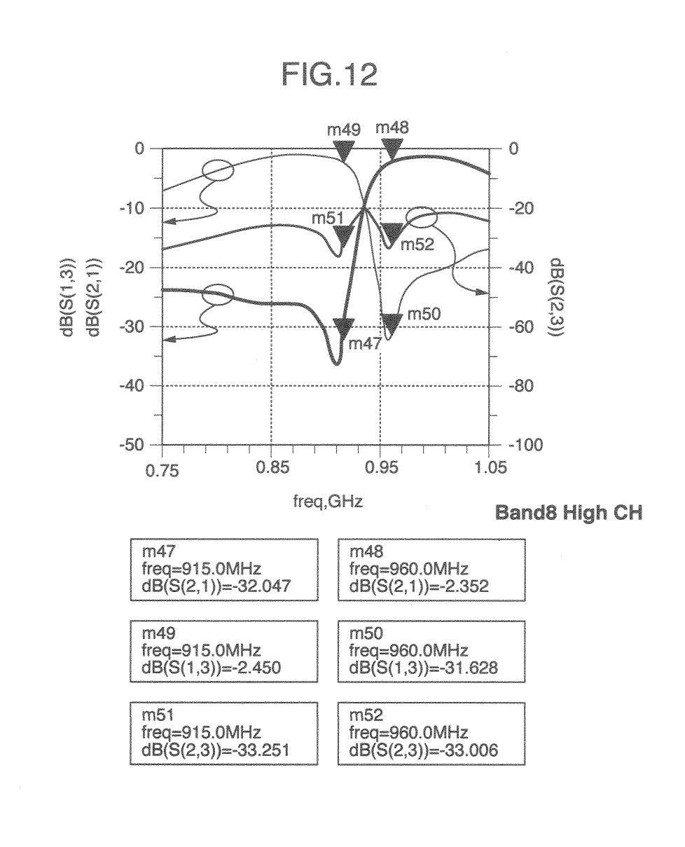

FIG. 12 shows a frequency characteristic of the tunable duplexer of the fifth embodiment tuned to the highest frequency band in Band8, with variable capacitors 10LR, 12LR at 1.2 pF, the variable capacitor 11LR at 3.15 pF, the variable capacitors 10LT, 12LT at 0.88 pF and the variable capacitor 11LT at 2.11 pF. In FIG. 12, a thick line represents a pass-through characteristic in a direction from the antenna 22L to the receiving terminal 2LR, a thin line represents a pass-through characteristic in a direction from the transmitting terminal 2LT to the antenna 22L and a medium thin line an isolation characteristic in a direction from the transmitting terminal 2LT to the receiving terminal 2LR. As shown in FIG. 12, the resonant frequency of the second pair of the variable capacitor 11LR and the fixed coil 8LR in the receiving tunable filter 33 matches the passband of the transmitting tunable filter 34, thus forming a notch. Further, the resonant frequency of the second pair of the variable capacitor 11LT and the fixed coil 8LT in the transmitting tunable filter 34 matches the passband of the receiving tunable filter 33, thus forming a notch. This results in a satisfactory isolation characteristic in a direction from the transmitting terminal 2LT to the receiving terminal 2LR.

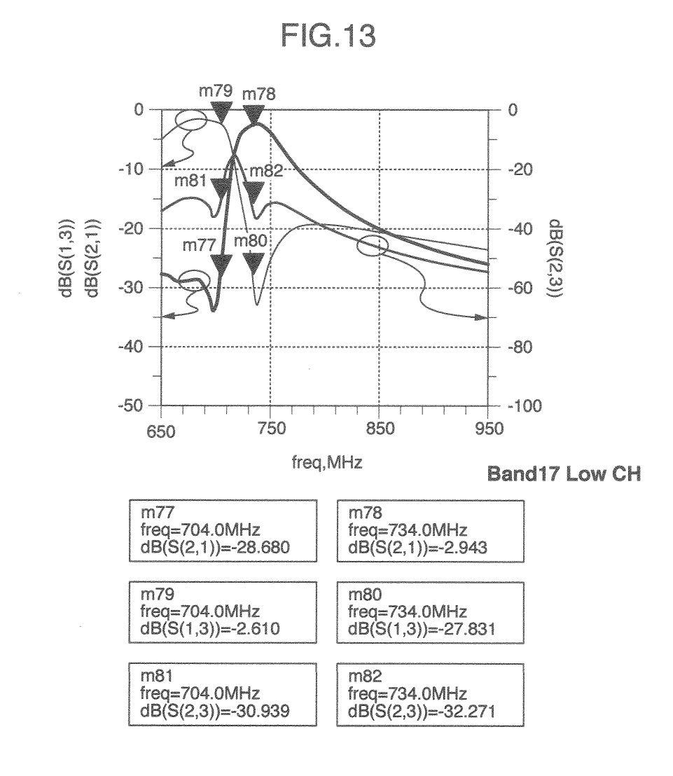

FIG. 13 shows a frequency characteristic of the tunable duplexer of the fifth embodiment tuned to the lowest frequency band in Band17, with variable capacitors 10LR, 12LR at 3.02 pF, the variable capacitor 11LR at 5.80 pF, the variable capacitors 10LT, 12LT at 2.30 pF and the variable capacitor 11LT at 4.55 pF. In FIG. 13, a thick line represents a pass-through characteristic in a direction from the antenna 22L to the receiving terminal 2LR, a thin line represents a pass-through characteristic in a direction from the transmitting terminal 2LT to the antenna 22L and a medium thin line an isolation characteristic in a direction from the transmitting terminal 2LT to the receiving terminal 2LR. As shown in FIG. 13, the resonant frequency of the second pair of the variable capacitor 11LR and the fixed coil 8LR in the receiving tunable filter 33 matches the passband of the transmitting tunable filter 34, thus forming a notch. Further, the resonant frequency of the second pair of the variable capacitor 11LT and the fixed coil 8LT in the transmitting tunable filter 34 matches the passband of the receiving tunable filter 33, thus forming a notch. This results in a satisfactory isolation characteristic in a direction from the transmitting terminal 2LT to the receiving terminal 2LR.

### Embodiment 6

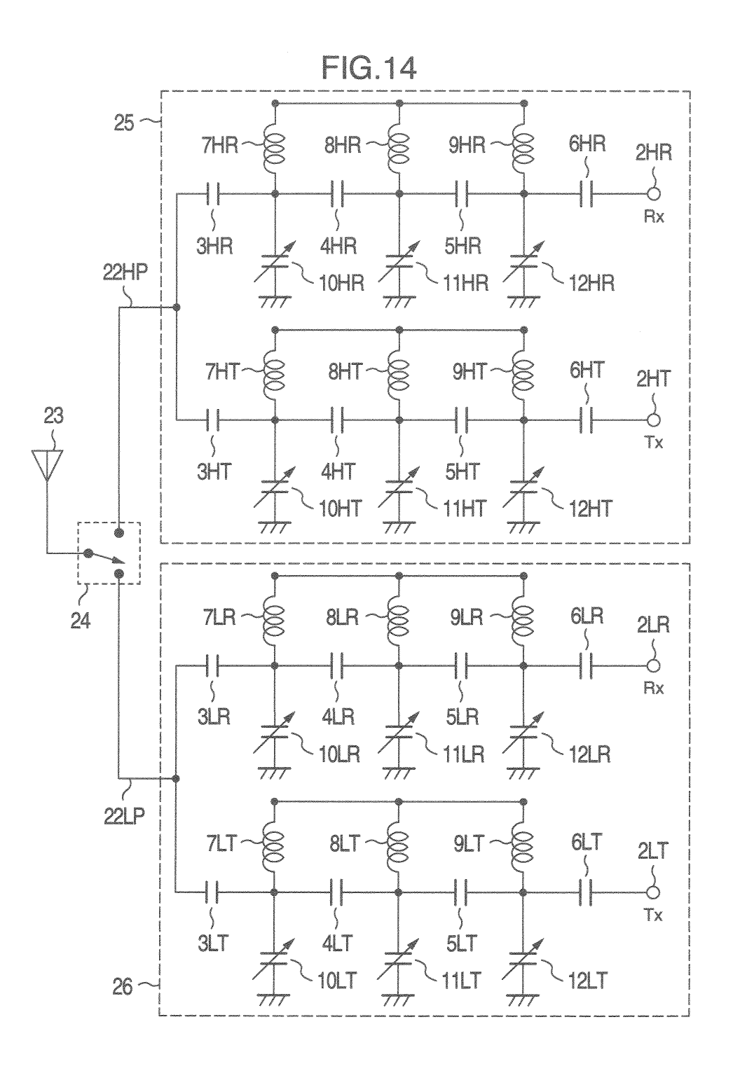

FIG. 14 shows a circuitry of a tunable duplexer module of the sixth embodiment. In this embodiment, the high-band tunable duplexer 25 uses the tunable duplexer of the fourth embodiment and the low-band tunable duplexer 26 uses the tunable duplexer of the fifth embodiment. An antenna side terminal 22HP of the high-band tunable duplexer 25 and an antenna side terminal 22LP of the low-band tunable duplexer 26 are connected through a SPDT switch 24 to an antenna 23. That is, the SPDT switch 24 selects between the high-band tunable duplexer 25 and the low-band tunable duplexer 26 for connection to the antenna 23. The SPDT switch is formed of GaAs (gallium arsenide) material. The tunable duplexer module of this configuration can be used as a mobile communication module that covers almost all bands of the communication systems such as WCDMA and LTE.

While, in all of the foregoing embodiments, solenoid coils are used as stationary coils, if their Q value is about 60 or higher at the operation frequency, other means may be used, such as IPD (Integrated Passive Device) coils in which solenoid coils are formed on a silicon substrate, or chip-laminated coils. Further, although in this embodiment chip capacitors are used as the fixed capacitors, it is also possible to use other means, such as IPD capacitors and MEMS capacitors, or coils formed as inner layer patterns in laminated substrates. Furthermore, although this embodiment uses MEMS variable capacitors as the variable capacitors, other means such as varicap may also be used. The constants shown in this embodiment are just one example and it is noted that desired tunable filters can be formed by using other constants than those described above, as needed, to be able to deal with other bands than Band1 and Band 11. Further, while bands used for WCDMA and LTE have been taken for example, adjusting the applied frequencies by changing the constants appropriately can make the device applicable to 4G (fourth generation mobile communication system).

### Embodiment 7

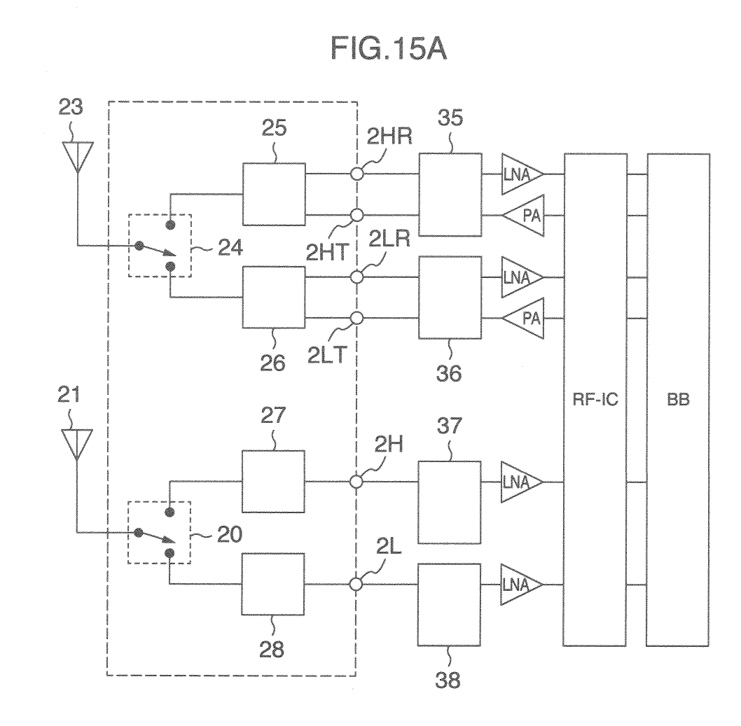

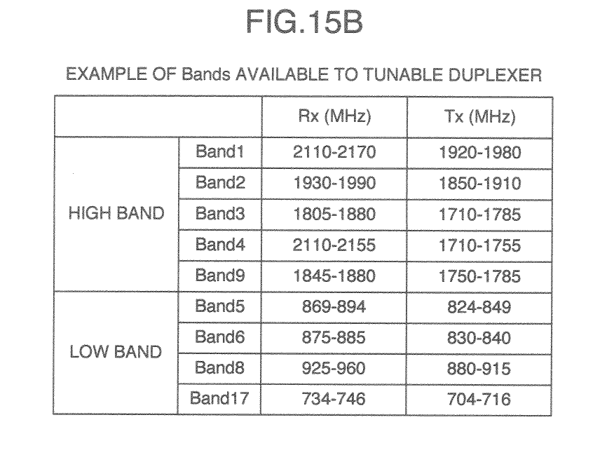

FIG. 15 is a block diagram of the seventh embodiment showing a tunable filter module and a tunable duplexer module of this invention applied to a multiband-enabled mobile communication terminal. As shown in this block diagram, the mobile terminal has a tunable duplexer module and a tunable filter module, the tunable duplexer module comprising the high-band tunable duplexer 25, the low-band tunable duplexer 26, the SPDT switch 24 and the antenna 23, the tunable filter module comprising the high-band tunable filter 27, the low-band tunable filter 28, the SPDT switch 20 and the antenna 21.

Main communication is done by transferring signals through the tunable duplexer module and, for improved reception quality, uses tunable filter module as the diversity receiver circuit. The high-band receiving terminal 2HR and transmitting terminal 2HT are connected to a high-band jamming wave and distortion canceler block 35 and the low-band receiving terminal 2LR and transmitting terminal 2LT are connected to a low-band jamming wave and distortion canceler block 36. The high-band and low-band received signals and transmitting signals are each connected through LNA and PA to RF-IC and BB (Base Band) blocks that perform subsequent steps of signal processing. The high-band receiving terminal 2H of the tunable filter module is connected to a high-band jamming wave and distortion canceler block 37 and the low-band receiving terminal 2L is connected to a low-band jamming wave and distortion canceler block 38. The high-band and low-band received signals in the tunable filter module are connected through LNA to RF-IC and BB blocks that perform subsequent steps of signal processing.

The mobile communication terminal of this configuration can handle multiple bands, such as shown in “Example of frequency bands available to tunable duplexer” of FIG. 15B, without having to use a large number of duplexers and diversity filters, and can be made small in size and simplified. While the configuration of this embodiment has been described to use the tunable filter module for a diversity reception circuit to obtain a very high reception sensitivity, it is also possible to provide a simplified configuration that uses only a tunable duplexer module that performs main signal processing.

1. A tunable filter comprising:
an input terminal;
an output terminal;
a first series-connected LC circuit composed of a first variable capacitor and a first fixed coil;
a second series-connected LC circuit composed of a second variable capacitor and a second fixed coil;
a third series-connected LC circuit composed of a third variable capacitor and a third fixed coil;
a first fixed capacitor with one of its ends connected to the input terminal and the other end connected to a connecting point of the first variable capacitor and the first fixed coil;
a second fixed capacitor with one of its ends connected to the output terminal and the other end connected to a connecting point of the second variable capacitor and the second fixed coil;
a third fixed capacitor with one of its ends connected to the connecting point of the first variable capacitor and the first fixed coil and the other end connected to a connecting point of the third variable capacitor and the third fixed coil; and
a fourth fixed capacitor with one of its ends connected to the connecting point of the second variable capacitor and the second fixed coil and the other end connected to the connecting point of the third variable capacitor and the third fixed coil;
wherein the frequencies of a passband and a stopband of the tunable filter are made variable by changing capacitance values of the variable capacitors.

2. A tunable filter module, comprising:
a high-frequency tunable filter having the tunable filter of claim 1 tuned to a frequency band higher than about 1.5 GHz;
a low-frequency tunable filter having the tunable filter of claim 1 tuned to a frequency band lower than about 1.5 GHz; and
an SPDT (Single Pole Dual Throw) switch;
wherein the SPDT switch has its input terminal connected to an antenna and its two throw-side terminals connected to the high-frequency tunable filter and the low-frequency tunable filter, respectively;
wherein the SPDT switch can select between the high-frequency tunable filter and the low-frequency tunable filter for connection to the antenna.

3. A tunable duplexer having the tunable filter of claim 1 as a first tunable filter and a second tunable filter;
wherein the first and the second tunable filter have their input ends connected to the antenna;
wherein constants of the third variable capacitor and the third fixed coil of the first tunable filter are adjusted so that a resonant frequency of the third variable capacitor and the third fixed coil matches the passband of the second tunable filter;
wherein constants of the third variable capacitor and the third fixed coil of the second tunable filter are adjusted so that a resonant frequency of the third variable capacitor and the third fixed coil matches the passband of the first tunable filter.

4. A tunable duplexer module comprising:
a high-frequency tunable duplexer having the tunable duplexer of claim 3 tuned to a frequency band higher than about 1.5 GHz;
a low-frequency tunable duplexer having the tunable duplexer of claim 3 tuned to a frequency band lower than about 1.5 GHz; and
an SPDT (Single Pole Dual Throw) switch;
wherein the SPDT switch has its input terminal connected to an antenna and its two throw-side terminals connected to the high-frequency tunable duplexer and the low-frequency tunable duplexer, respectively;
wherein the SPDT switch can select between the high-frequency tunable duplexer and the low-frequency tunable duplexer for connection to the antenna.

5. A tunable filter according to claim 1, wherein the fixed coils are solenoid coils.

6. A tunable filter module according to claim 2, wherein the fixed coils are solenoid coils.

7. A tunable duplexer according to claim 3, wherein the fixed coils are solenoid coils.

8. A tunable duplexer module according to claim 4, wherein the fixed coils are solenoid coils.

9. A tunable filter according to claim 1, wherein the variable capacitors are MEMS (Micro Electro Mechanical Systems) variable capacitors.

10. A tunable filter module according to claim 2, wherein the variable capacitors are MEMS (Micro Electro Mechanical Systems) variable capacitors.

11. A tunable duplexer according to claim 3, wherein the variable capacitors are MEMS (Micro Electro Mechanical Systems) variable capacitors.

12. A tunable duplexer module according to claim 4, wherein the variable capacitors are MEMS (Micro Electro Mechanical Systems) variable capacitors.

13. A mobile communication terminal comprising:
a tunable filter module of claim 2;
a tunable duplexer module of claim 4;
a jamming wave canceler block; and
a distortion canceler block.
